(19) United States
(12) Patent Application Publication
(10) Pub. No.: US 2021/0318161 A1
(43) Pub. Date: Oct. 14, 2021

(54) SENSOR APPARATUS COMPRISING A HOUSING AND AN AT LEAST ONE-AXIS VIBRATION SENSOR

(71) Applicant: Robert Bosch GmbH, Stuttgart (DE)

(72) Inventors: Ricardo Ehrenpfordt, Zwickau (DE); Magnus Christian Proebster, Kusterdingen (DE); Max Schellenberg, Ditzingen (DE)

(21) Appl. No.: 17/272,879

(22) PCT Filed: Aug. 20, 2019
(86) PCT No.: PCT/EP2019/072288

§ 371 Date: Mar. 2, 2021

(30) Foreign Application Priority Data
Sep. 12, 2018 (DE) 10 2018 215 496.1

(51) Int. Cl. G01H 1/12

(52) U.S. Cl. CPC G01H 1/12; H05K 1/189

(57) ABSTRACT

A sensor apparatus having a housing and having an at least single-axis vibration sensor. The housing has wall elements that are disposed in such a way that the wall elements together surround the vibration sensor. The housing has a stiffening structure that connects the wall elements rigidly to one another. The vibration sensor is coupled mechanically solidly to the stiffening structure. The housing has a first through hole along a first axis and a second through hole along a second axis. The first axis and the second axis are substantially perpendicular to one another.

### FIELD

The present invention relates to a sensor apparatus having a housing and having an at least single-axis vibration sensor, the housing having wall elements that are disposed in such a way that the wall elements together surround the vibration sensor.

### BACKGROUND INFORMATION

A sensor apparatus of this kind can be mounted, for example, on a unit that is to be monitored, and thereby enables vibrations of the unit to be detected. Based on the detected vibrations, for example, a possible malfunction of the unit can be inferred.

### SUMMARY

The present invention proceeds from a sensor apparatus having a housing and having an at least single-axis vibration sensor, the housing having wall elements that are disposed in such a way that the wall elements together enclose the vibration sensor.

A “vibration sensor” is to be understood as an electrical component that can detect vibrations. These vibrations are to be characterized as oscillations of objects or substances. A vibration sensor of this kind can be configured, for example, capacitively or as a piezoelement.

A “wall element” is to be understood as a planar element that, in particular together with other wall elements, forms part of a housing inside which constituents of the sensor apparatus can be disposed. The walls surround the constituents in such a way that only passages through which the sensor apparatus can be populated, and which can be closed off by covering elements, are present.

In accordance with one aspect of the present invention, the housing has a stiffening structure that connects the wall elements rigidly to one another, the vibration sensor being coupled mechanically solidly to the stiffening structure, and the housing having a first through hole along a first axis and a second through hole along a second axis, the first axis and the second axis being substantially perpendicular to one another.

It may be advantageous here that the vibrations acting on the sensor apparatus are conveyed via the wall elements and the stiffening structure in undamped fashion to the vibration sensor. Based on those vibrations it is possible, for example, to infer a defect of an external unit on which the sensor apparatus is mounted. By way of the two through holes embodied perpendicularly to one another it is furthermore possible to use a single-axis vibration sensor by way of which it is possible in turn, depending on the mounting of the sensor apparatus on the external unit, to select one relevant spatial direction, from among all three spatial directions, which is to be monitored. A single-axis vibration sensor has the advantage that it typically exhibits higher resolution and better quality as compared with a multi-axis vibration sensor, and furthermore is of less-complex configuration. A multi-axis vibration sensor having the same properties as a single-axis vibration sensor is therefore usually considerably more expensive.

A “stiffening structure” is to be understood as a part of the housing which rigidly connects the wall elements in such a way that the vibrations introduced from outside can be conveyed particularly effectively. A “rigid” connection is to be understood in turn as a connection that is mechanically solid and consequently not elastic.

A “through hole” is to be understood, for example, as a continuous aperture through which, for example, a bolt or a nail can be guided in order to mount the sensor apparatus on an external unit.

The first axis and the second axis are in particular designed in such a way that they intersect at a point, that point particularly preferably being disposed centeredly with respect to the wall elements. In particular, the vibration sensor can furthermore be disposed in such a way that it detects vibrations along the first or the second axis.

In an example embodiment of the sensor apparatus according to the present invention, provision is made that the first through hole and/or the second through hole leads through wall elements and through the stiffening structure.

It may be advantageous here that vibrations can be directed even more effectively and with less damping to the vibration sensor.

According to an example embodiment of the sensor apparatus according to the present invention, provision is made that the sensor apparatus has at least a first circuit carrier and a second circuit carrier, the first circuit carrier and the second circuit carrier each being disposed, parallel to a plane, inside the wall elements and outside the stiffening structure, and having an electrical connection to one another; the plane extending parallel to the first axis and to the second axis, and the vibration sensor being disposed on the first or the second circuit carrier.

It may be advantageous here that the constituents of the sensor apparatus can be distributed among the two circuit carriers, with the result that the extent of the sensor apparatus in terms of width is minimized and, for example, a uniform and compact cube shape can be created.

According to an example embodiment of the sensor apparatus according to the present invention, provision is made that the stiffening structure is disposed between the first circuit carrier and the second circuit carrier and has at least one passage through which the electrical connection between the first circuit carrier and the second circuit carrier is guided.

It may be advantageous here that as a result of the corresponding disposition of the two circuit carriers, tilting modes of the housing can be decreased when the sensor apparatus is mounted on the external unit.

The electrical connection transmits in particular both electrical energy and data between the circuit carriers, one of the circuit carriers being correspondingly connected externally to an energy supply lead and to a communication lead.

It would alternatively also be possible, however, for both circuit carriers to be disposed respectively above or below the stiffening structure.

In accordance with an example embodiment of the sensor apparatus according to the present invention, provision is made that the electrical connection is embodied as a flex PCB.

It may be advantageous here that this represents a simple capability for electrically connecting the two circuit carriers. In particular, no temperature-intensive soldering steps are necessary in the context of assembly, since the flex PCB can be adhesively bonded onto the respective circuit carriers and then electrically contacted to them by wire bonding. It is particularly advantageous in this case if one circuit carrier is equipped with a flex PCB constituting a rigid flex PCB, and the other circuit carrier is mechanically and electrically contacted to it. A “flex PCB” is to be understood here as a flexible circuit carrier.

If both circuit carriers are disposed respectively above or below the stiffening structure, the combination of a first circuit carrier, second circuit carrier, and electrical connection can be configured as a continuous rigid flex PCB.

In accordance with an example embodiment of the sensor apparatus according to the present invention, provision is made that the first and/or the second circuit carrier is bolted and/or adhesively bonded into the housing, in particular is bolted and/or adhesively bonded onto the stiffening structure.

It may be advantageous here that this represents a simple and inexpensive installation capability for securing the circuit carriers in the sensor apparatus.

In accordance with an example embodiment of the sensor apparatus according to the present invention, provision is made that the wall elements of the housing have a square cross section and the stiffening structure is disposed between the wall elements, the stiffening structure being embodied in particular in a cross shape.

It may be advantageous here that as a result of the square cross section that results in a cubic shape for the sensor apparatus, the sensor apparatus can be mounted in particularly simple fashion onto an external unit, and it is possible to select in that context which of the three spatial directions is to be monitored. In addition, thanks to the cross-shaped configuration of the stiffening structure, passages for electrical connection of the circuit carriers can be created in particularly simple fashion without greatly impairing the mechanical stability of the housing. Alternatively, the stiffening structure can also be configured over the entire area between the wall elements, the circuit carriers then being disposed parallel to the main plane of extent of the stiffening structure and, specifically, both above or below the stiffening structure. In this case the stiffening structure can particularly advantageously serve as a covering element for the housing and can completely close off an opening formed by the walls.

In accordance with an example embodiment of the sensor apparatus according to the present invention, provision is made that the stiffening structure has an aperture that is at least partly filled with a mechanically solid sealing material, the vibration sensor penetrating at least partly into the sealing material. It is advantageous here that temperature fluctuations acting on the sensor apparatus can be compensated for by the sealing material, with the result that the mechanically solid coupling of the vibration sensor to the stiffening structure is maintained in optimally long-lived fashion.

A “mechanically solid sealing material” is to be understood as a material that is inelastic and can thus convey vibrations from the stiffening structure to the vibration sensor in undamped fashion. A sealing material of this kind can be, for example, a correspondingly embodied adhesive or thermosetting plastic.

In accordance with an example embodiment of the sensor apparatus according to the present invention, provision is made that the vibration sensor is embodied as an SOIC component, a housing of the vibration sensor penetrating at most halfway into the sealing material.

It may be advantageous here that an SOIC component is inexpensive and can be installed in simple fashion on the circuit carrier. In addition, the SOIC component can be disposed in such a way that its contact pins do not penetrate into the sealing material. Mechanical stress on the individual contact pins of the SOIC component can thereby be avoided or decreased.

In accordance with an example embodiment of the sensor apparatus according to the present invention, provision is made that the wall elements and the stiffening structure are embodied on one piece.

It may be advantageous here that simple and inexpensive manufacture of the housing is made possible. In addition, there are no gaps between the individual components which might negatively influence the rigidity of the housing.

The one-piece housing can be manufactured, for example, by material-removing machining or by way of a molding process. In particular, the wall elements and/or the stiffening structure are manufactured substantially from metal or plastic. The metal used here is particularly preferably aluminum or steel.

“Substantially from metal or plastic” is to be understood here to mean that the wall elements and/or the stiffening structure encompass principally one or several metallic substances or plastics and only negligibly, for example in the range of single-digit percentages, one or several non-metallic substances or non-plastics. These non-metallic substances or non-plastics can be, for example, contaminants. The non-metallic substances or non-plastics can, however, also be deliberately blended in so as to influence properties such as flexibility or durability, although other properties, for example mechanical rigidity, should be influenced very little or not at all.

In accordance with an example embodiment of the sensor apparatus according to the present invention, provision is made that openings of the housing which are constituted by the wall elements are respectively closed off by a cover element, the stiffening structure in particular being embodied in planar fashion as one of the covering elements.

It may be advantageous here that these covering elements, together with the wall elements, can protect the electrical constituents in the interior of the housing from external influences, for example dirt or moisture, and furthermore can be installed easily.

For mounting, for example an adhesive process can be carried out, or the cover elements can be connected to the wall elements by laser welding.

In particular, one of the covering elements can be constituted by the stiffening structure, which is correspondingly embodied over the entire surface between the wall elements. The first and the second circuit carrier are then both respectively located on one side of the main plane of extent of the stiffening structure inside the housing.

In accordance with an example embodiment of the sensor apparatus according to the present invention, provision is made that at least one of the cover elements has a connector plug for connection to an external unit, the connector plug extending through the cover element and being electrically connected to the first or to the second circuit carrier.

It may be advantageous here that the combination of a covering element with a connector plug and a circuit carrier can be prefabricated as one component and can then be installed in simple and rapid fashion.

In accordance with an example embodiment of the sensor apparatus according to the present invention, provision is made that the sensor apparatus has a communication lead and an energy supply lead for connection to an external unit, the communication lead and energy supply lead in particular being configured as one lead.

It may be advantageous here that both data and energy can be transferred. In particular, with one common lead space can thereby be saved, with the result that the sensor apparatus can be kept small.

The communication lead and energy supply lead are in particular integrated into the connector plug and are configured, for example, as Ethernet and power over Ethernet.

A “lead” is to be understood as an electrical connecting element that, in particular, can have several strands. An electrical connecting element of this kind can be, for example, a metallic cable.

In accordance with an example embodiment of the sensor apparatus according to the present invention, provision is made that the vibration sensor is disposed centeredly with respect to the wall elements.

It may be advantageous here that optimal vibration transfer from outside to the vibration sensor can occur, said transfer being independent of how the sensor apparatus is mounted on the external unit.

In accordance with an example embodiment of the sensor apparatus according to the present invention, provision is made that the housing is filled at least in part with a sealing compound, in particular a plastic sealing compound.

It may be advantageous here that constituents in the interior of the housing are even better protected.

In particular, the entire interior space of the housing is completely filled with the sealing compound. Alternatively, for example, the sealing compound can be disposed only between the cover element with connector plug and the stiffening structure.

The sealing compound can be, for example, a thermosetting plastic.

A further advantage of the present invention is that the corresponding configuration according to the present invention of the sensor apparatus makes possible particularly simple manufacture of the sensor apparatus, in which standard methods of production and connection engineering can be used. For example, pick-and-place with exclusively horizontal component population, and exclusively horizontal steps of production and connection engineering, are required. No rotational motions are therefore necessary in the context of assembly of the sensor apparatus. As a result, the housing can be populated using only two steps. In a first step, the first circuit carrier having the vibration sensor is introduced and is correspondingly attached to the stiffening structure. In a second step the second circuit carrier, which is already connected to the flex PCB and to the cover element with connector plug, is introduced. All that is then required in order to obtain the completed sensor apparatus is for the flex PCB to be contacted to the first circuit carrier, and for the lower covering element to be applied. Alternatively, of course, firstly the second circuit carrier and then the first circuit carrier can also be introduced into the housing.

### BRIEF DESCRIPTION OF THE DRAWINGS

FIG. 1 shows an exemplifying embodiment of a sensor apparatus according to the present invention.

FIG. 2 shows an exemplifying embodiment of a housing of a sensor apparatus according to the present invention as shown in FIG. 1, without covering elements.

FIG. 3 is a section through a sensor apparatus according to the present invention as shown in FIG. 1, perpendicularly to a first axis.

FIG. 4 is a plan view of a sensor apparatus according to the present invention as shown in FIG. 1, from below and without a cover element.

### DETAILED DESCRIPTION OF EXAMPLE EMBODIMENTS

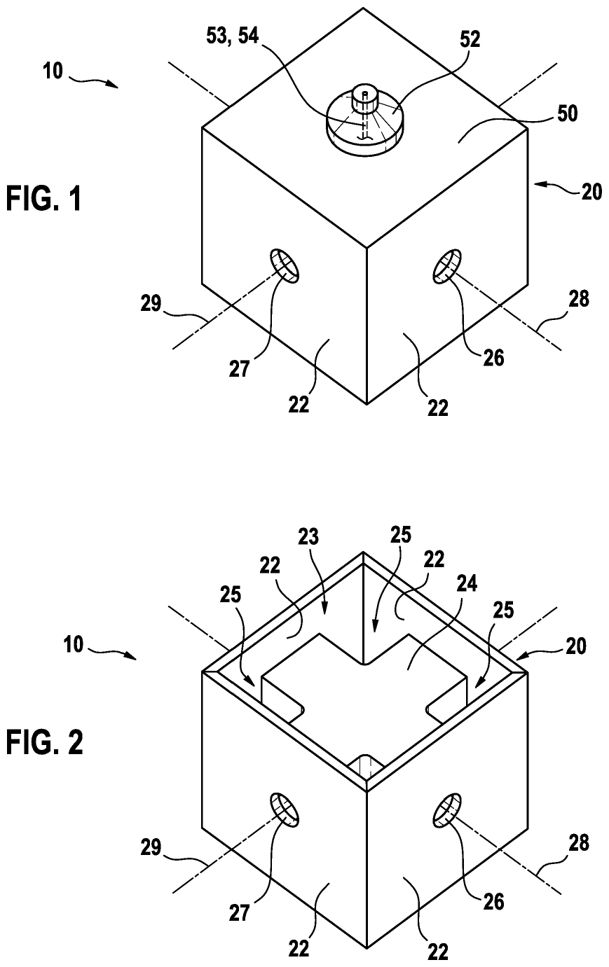

FIG. 1 shows an exemplifying embodiment of a sensor apparatus according to the present invention.

A sensor apparatus 10 is depicted. Sensor apparatus 10 has a housing 20. Housing 20 in turn has wall elements 22. The sensor apparatus furthermore has a covering element 50. Wall elements 22 and cover element 50 are disposed in a cube shape. Cover element 50 has a connector plug 52 for connecting sensor apparatus 10 to an external unit (not illustrated). Sensor apparatus 10 furthermore has a communication lead 53 and an energy supply lead 54, which are configured as a single lead and are integrated into connector plug 52. Communication lead 53 can be embodied as an Ethernet lead, energy supply lead 54 using that Ethernet lead to allow electrical energy to be delivered from outside to sensor apparatus 10 via power over Ethernet.

Housing 20 furthermore has a first through hole 26 along a first axis 28 and a second through hole 27 along a second axis 29, which pass through corresponding wall elements 22. First axis 28 and second axis 29 are substantially perpendicular to one another and intersect in particular at one point. This intersection point is disposed in particular centeredly with respect to wall elements 22. The cross section of first through hole 26 and of second through hole 28 is configured circularly, but alternatively could also have a different shape. By way of first through hole 26 and second through hole 27, sensor apparatus 10 can be fastened on an external unit, for example by way of a screw connection.

FIG. 2 shows an exemplifying embodiment of a housing of a sensor apparatus according to the present invention as shown in FIG. 1, without covering elements.

Wall elements 22 of housing 20 are once again depicted. Wall elements 22 form an opening 23 that is not, as in FIG. 1, closed off by a covering element 50. In addition, housing 20 has a stiffening structure 24 that connects wall elements 22 rigidly to one another. Stiffening structure 24 is configured in a cross shape, thereby producing passages 25 that extend along the inner edges of wall elements 22. A further result thereof is that, in particular, oppositely located wall elements 22 are mechanically connected to one another and correspondingly stiffened. First through hole 26 and second through hole 27 pass both through wall elements 22 and through stiffening structure 24. In particular, stiffening structure 24 and wall elements 22 can be embodied in one piece and, for example, can have been manufactured using an injection-molding process.

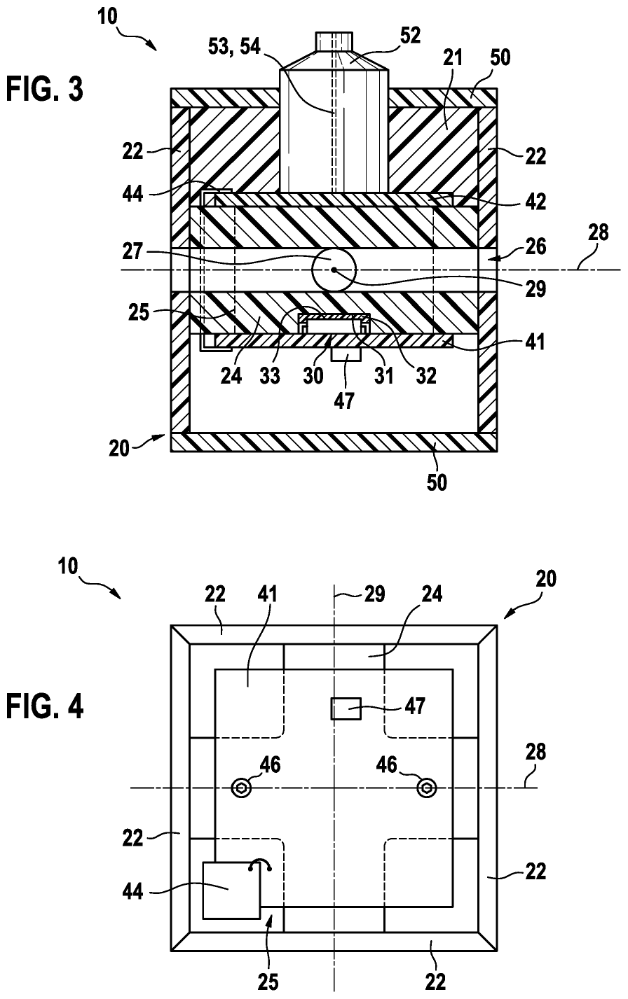

FIG. 3 is a section through a sensor apparatus according to the present invention as shown in FIG. 1, perpendicularly to a first axis.

It depicts a section perpendicular to first axis 28 of sensor apparatus 10 depicted in FIG. 1. Sensor apparatus 10 has a first circuit carrier 41 and a second circuit carrier 42. First circuit carrier 41 and second circuit carrier 42 are each surrounded by wall elements 22 and are disposed outside stiffening structure 24 parallel to a plane, and have an electrical connection 44 to one another. The corresponding plane extends parallel to first axis 28 and to second axis 29. First circuit carrier 41 is disposed below stiffening structure 24, and second circuit carrier 42 above stiffening structure 24. Electrical connection 44 is embodied in particular as a flex PCB and is guided through a passage 25 in stiffening structure 24.

Second circuit carrier 42 is electrically connected to connector plug 52, for example by the fact that connector plug 52 is soldered onto second circuit carrier 42. In particular, connector plug 52 is thereby also solidly mechanically connected to second circuit carrier 42. The open space between stiffening structure 24 and covering element 50 with connector plug 52 is filled with a sealing compound 21.

An, in particular, single-axis vibration sensor 30 is disposed on first circuit carrier 41. Vibration sensor 30 is connected mechanically solidly to stiffening structure 24. This mechanically solid connection is achieved here by the fact that stiffening structure 24 has an aperture 31 that is filled at least in part with a mechanically solid sealing material 32. Vibration sensor 30 in turn penetrates at least partly into this sealing material 32. Vibration sensor 30 is embodied in particular as an SOIC component, housing 33 of vibration sensor 30 penetrating only at most halfway into sealing material 32. As a result, corresponding contact pins of vibration sensor 30, with which vibration sensor 30 is soldered onto first circuit carrier 41, can be disposed outside sealing material 32. First circuit carrier 41 is furthermore disposed in secured fashion on stiffening structure 24, in particular by way of a screw connection. First circuit carrier 41 could also, alternatively or additionally, be adhesively bonded onto stiffening structure 24. As a further alternative, first circuit carrier 41 could be secured, for example, on wall elements 22 rather than on stiffening structure 24. Corresponding securing possibilities also apply to second circuit carrier 42. Alternatively, the second circuit carrier could also simply be fastened on connector plug 52 in order to define a corresponding location in housing 20.

Also depicted by way of example on first circuit carrier 41 is a further constituent 47, which can be embodied e.g. as a microcontroller, communication unit, memory unit, DC/DC converter, or the like. Such further constituents 47 can be correspondingly disposed as necessary on first circuit carrier 41 and on second circuit carrier 42.

Sensor apparatus 10 could also additionally have a temperature sensor, which can be disposed on first circuit carrier 41. The temperature sensor, similarly to vibration sensor 30, can penetrate into a further passage of stiffening structure 24 which at least partly filled with a sealing material. The sealing material and housing 20 should exhibit good thermal conductivity, so that a temperature of an external unit on which sensor apparatus 10 is mounted can correspondingly be reliably measured.

FIG. 4 is a plan view of a sensor apparatus according to the present invention as shown in FIG. 1, from below and without a cover element.

Sensor apparatus 10, with housing 20 that is constituted from wall elements 22 and stiffening structure 24, is once again depicted. First circuit structure 41 is disposed on stiffening structure 24 and is secured on stiffening structure 24 by way of screws 46. Electrical connection 44 between first circuit carrier 41 and second carrier 42 is also configured as a flex PCB, which is guided through a passage 25 in stiffening structure 24. This flex PCB is adhesively bonded onto first circuit carrier 41 and is electrically connected to first circuit carrier 41 by way of at least one wire bond. The electrical connection of the flex PCB to second circuit carrier 42 can, for example, be effected similarly or can be embodied directly as a rigid flex PCB.

1-15. (canceled)

16. A sensor apparatus, comprising:
a housing; and
an at least single-axis vibration sensor, the housing having wall elements that are disposed in such a way that the wall elements together surround the vibration sensor;
wherein the housing has a stiffening structure that connects the wall elements rigidly to one another, the vibration sensor being coupled mechanically solidly to the stiffening structure, and the housing having a first through hole along a first axis and a second through hole along a second axis, the first axis and the second axis being substantially perpendicular to one another.

17. The sensor apparatus as recited in claim 16, wherein the first through hole and/or the second through hole leads through at least some of the wall elements and through the stiffening structure.

18. The sensor apparatus as recited in claim 16, wherein the sensor apparatus has at least a first circuit carrier and a second circuit carrier, the first circuit carrier and the second circuit carrier each being disposed, parallel to a plane, inside the wall elements and outside the stiffening structure, and having an electrical connection to one another, wherein the plane extends parallel to the first axis and to the second axis, and wherein the vibration sensor is disposed on the first circuit carrier or on the second circuit carrier.

19. The sensor apparatus as recited in claim 18, wherein the stiffening structure is disposed between the first circuit carrier and the second circuit carrier and has at least one passage through which the electrical connection between the first circuit carrier and the second circuit carrier is guided.

20. The sensor apparatus as recited in claim 18, wherein the electrical connection is a flex PCB.

21. The sensor apparatus as recited in claim 18, wherein the first circuit carrier and/or the second circuit carrier is bolted and/or adhesively bonded into the housing.

22. The sensor apparatus as recited in claim 18, wherein the first circuit carrier and/or the second circuit carrier is bolted and/or adhesively bonded onto the stiffening structure.

23. The sensor apparatus as recited in claim 16, wherein the wall elements of the housing have a square cross section and the stiffening structure is disposed between the wall elements, the stiffening structure being in a cross shape.

24. The sensor apparatus as recited in claim 16, wherein the stiffening structure has an aperture that is at least partly filled with a mechanically solid sealing material, the vibration sensor penetrating at least partly into the sealing material.

25. The sensor apparatus as recited in claim 24, wherein the vibration sensor is embodied as an SOIC component, a housing of the vibration sensor penetrating at most halfway into the sealing material.

26. The sensor apparatus as recited in claim 16, wherein the wall elements and the stiffening structure are formed on one piece.

27. The sensor apparatus as recited in claim 18, wherein openings of the housing which are constituted by the wall elements are respectively closed off by a cover element, the stiffening structure being embodied in planar fashion as one of the covering elements.

28. The sensor apparatus as recited in claim 27, wherein at least one of the cover elements has a connector plug for connection to an external unit, the connector plug extending through the cover element and being electrically connected to the first circuit carrier or to the second circuit carrier.

29. The sensor apparatus as recited in claim 16, wherein the sensor apparatus has a communication lead and an energy supply lead for connection to an external unit, the communication lead and energy supply lead being configured as one lead.

30. The sensor apparatus as recited in claim 16, wherein the vibration sensor is disposed centeredly with respect to the wall elements.

31. The sensor apparatus as recited in claim 16, wherein the housing is filled at least in part with a plastic sealing compound.
